(19) United States
(12) Patent Application Publication
(10) Pub. No.: US 2015/0107643 A1
(43) Pub. Date: Apr. 23, 2015

(54) PHOTOVOLTAIC MODULE AND METHOD FOR PRODUCING SUCH A MODULE

(71) Applicant: Commissariat a I'energie atomique et aux ene alt, Paris (FR)

(72) Inventors: Philippe Voarino, Nice (FR); Paul Lefillastre, Paris (FR)

(73) Assignee: Commissariat a I'energie atomique et aux ene alt, Paris (FR)

(21) Appl. No.: 14/400,125

(22) PCT Filed: May 7, 2013
(86) PCT No.: PCT/EP2013/059439

§ 371 Date: Nov. 10, 2014

(30) Foreign Application Priority Data
May 11, 2012 (FR) 12 54337

(51) Int. Cl. H01L 31/05

(52) U.S. Cl. CPC H01L 31/0504
USPC 136/244; 438/80

(57) ABSTRACT

A photovoltaic module including first photovoltaic cells and second photovoltaic cells, electrically connected to each other and arranged adjacent to each other, in which a value of a short circuit current of each of the first photovoltaic cells is less than a value of a short circuit current of each of the second photovoltaic cells of the photovoltaic module, and the first photovoltaic cells are arranged at edges and/or ends of the photovoltaic module.

### TECHNICAL FIELD

The invention relates to a photovoltaic module in which the arrangement of the photovoltaic cells within the module depends on the value of their short-circuit current I_{SC}. The invention relates to a method of producing such a photovoltaic module.

### STATE OF PRIOR ART

A photovoltaic module, also called photovoltaic panel or a solar panel, comprises a plurality of photovoltaic cells electrically connected to each other such that the photovoltaic module forms a DC current generator, the current being generated by photovoltaic conversion of photon radiation received by the cells. When such a photovoltaic module is made, the photovoltaic cells of the module are preferably chosen such that they are as similar to each other as possible in terms of electrical photovoltaic conversion characteristics. This is intended to minimise the part of the light flux received by the cells that is not converted into electricity by the cells, but also to avoid creating hot spots within the module. Such hot spots are sources of premature degradation of modules and may lead to local overheating or even cause fires. The global efficiency of the photovoltaic module is also affected when the cells of the module are not perfectly matched, in other words chosen as a function of the similarity of their electrical parameters.

The “Analysis and Control of Mismatch Power Loss in Photovoltaic Arrays” document by David Roche et al., Progress in Photovoltaics: research and applications, vol. 3, 115-127, 1995, describes different strategies for matching photovoltaic cells within a photovoltaic module.

### PRESENTATION OF THE INVENTION

One purpose of this invention is to disclose a photovoltaic module within which the location or position of each photovoltaic cell is optimised so as to increase the solar energy/electrical energy conversion capacity of the photovoltaic module.

To achieve this, a photovoltaic module is proposed comprising first photovoltaic cells and second photovoltaic cells electrically connected to each other and arranged adjacent to each other, in which the value of the short circuit current of each of the first photovoltaic cells is less than or equal to the value of the short circuit current of each of the second photovoltaic cells of the photovoltaic module and the first photovoltaic cells are arranged at the edges and/or ends of the photovoltaic module.

This invention relates to a photovoltaic module comprising first photovoltaic cells and second photovoltaic cells electrically connected to each other and arranged adjacent to each other, in which each of the first photovoltaic cells has a short circuit current with a value less than the short circuit current of each of the second photovoltaic cells of the photovoltaic module and are arranged at the edges and/or ends of the photovoltaic module.

Since the photovoltaic cells that have the lowest short circuit currents, called the first photovoltaic cells, are arranged at one or several edges of the photovoltaic module that corresponds to the zone(s) of the module in which the reflected light is the strongest, the other photovoltaic cells called second photovoltaic cells and that have the highest short circuit currents and that are arranged for example at the centre of the module are therefore designed to be overilluminated relative to the first photovoltaic cells.

The first photovoltaic cells are arranged at the edges and/or ends of the photovoltaic module, corresponding to zones in the module in which illumination is strongest, particularly due to reflection and light diffusion from the backsheet (protection film at the back of the photovoltaic module), from metal interconnections and from the frame of the photovoltaic module.

Thus, for a given batch of photovoltaic cells that will be used in the photovoltaic module, the conversion efficiency of the photovoltaic module is optimised by judiciously choosing the locations of the photovoltaic cells within the module as a function of the value of their short circuit current I_{SC}. Such optimisation can improve the short circuit current of the photovoltaic module, resulting in a gain in the short circuit current of the module that can be higher than about 1%.

The invention can be applied to any type of photovoltaic cell.

The description also discloses a photovoltaic module comprising a plurality of photovoltaic cells electrically connected to each other and arranged adjacent to each other, in which the value of the short circuit current for each of the photovoltaic cells located at the edges and/or ends of the photovoltaic module is less than or equal to the value of the short circuit current for each of the other photovoltaic cells of the photovoltaic module that are not located at the edges and/or ends of the module.

A photovoltaic cell located at one of the edges of the photovoltaic module may correspond to a cell that comprises at least one of its sides that is not adjacent to at least one other photovoltaic cell of the module. A photovoltaic cell at one of the ends of the photovoltaic module may correspond to a cell that has at least two of its sides not facing at least one other of the photovoltaic cells of the module.

A photovoltaic module is also disclosed comprising photovoltaic cells of a first group arranged at the outside edges of the photovoltaic module and around the periphery of photovoltaic cells of a second group, in other words around these cells, in which each of the photovoltaic cells of the first group has a value of the short circuit current less than or equal to the value of the short circuit current of each of the photovoltaic cells of the second group.

Each photovoltaic cell of the photovoltaic module may have a fill factor greater than about 0.70 (or 70%) and preferably greater than or equal to about 0.75 (or 75%). Such a fill factor corresponds to the fill factor specific to each cell, measured before the cells are organised into modules.

The photovoltaic cells of the photovoltaic module may be arranged adjacent to each other to form a rectangular-shaped matrix of M×N cells, the photovoltaic module comprising 2(M+N−2) first photovoltaic cells, where M and N are integers greater than or equal to 3. In this case, the photovoltaic module may comprise M·N−2(M+N−2) second photovoltaic cells. M and N may have different or similar values.

In this case, four first photovoltaic cells may be arranged in the corners of the rectangular-shaped matrix and the value of the short circuit current of each of said four first photovoltaic cells may be less than or equal to the value of the short circuit current of each of the other first photovoltaic cells. The corners of the matrix may correspond to the ends of the photovoltaic module.

It is also possible that M or N is less than 3. Thus, it is possible to have N=1, the photovoltaic cells of the module in this case being arranged in the form of a row of M cells. The first photovoltaic cells, corresponding to two photovoltaic cells, may be cells arranged at the ends of the row, even when there are more than two cells for which the value of the short circuit current is less than that for the other cells. The same is true if N=2, the first photovoltaic cells, corresponding to four photovoltaic cells, may be cells arranged at the ends of the two rows of cells. In this type of configuration, the term “at the periphery of” may be equally understood as meaning “at the ends of”.

The photovoltaic cells of the photovoltaic module may be arranged adjacent to each other to form one or two rows of P photovoltaic cells, the photovoltaic module comprising two or four first photovoltaic cells arranged at the ends of the row(s) of P photovoltaic cells, where P is an integer greater than or equal to 3.

It is also possible that the shape of the photovoltaic module is not rectangular, for example it may be hexagonal or even “round” (the cells being arranged adjacent to each other following a pattern approximately forming a disk). The first photovoltaic cells for which the short circuit current is less than the short circuit current of the other cells may be placed at the edge of the module.

A method of producing a photovoltaic module is also disclosed, comprising at least the following steps:
select first photovoltaic cells among a set of photovoltaic cells that will form part of the photovoltaic module, the value of the short circuit current of each first photovoltaic cell being less than or equal to the value of the short circuit current of each of second photovoltaic cells corresponding to cells not selected in the set of photovoltaic cells;
arrange the set of photovoltaic cells adjacent to each other and such that the first photovoltaic cells are located at the edges and/or the ends of the photovoltaic module;
make electrical connections between the set of photovoltaic cells.

A method of producing a photovoltaic module is also disclosed comprising at least the following steps:
select photovoltaic cells to create a first group that will be located at the external edges of the photovoltaic module from among a set of photovoltaic cells that will form part of the photovoltaic module, such that the value of the short circuit current of each photovoltaic cell of the first group is less than or equal to the short circuit current of each of the photovoltaic cells of a second group corresponding to the cells not selected in the set of photovoltaic cells;
arrange the photovoltaic cells of the first group around the periphery of the photovoltaic cells of the second group.

The invention also relates to a method of producing a photovoltaic module comprising at least the following steps:
select first photovoltaic cells among a set of photovoltaic cells that will form part of the photovoltaic module, in which the value of the short circuit current of each first photovoltaic cell is less than the value of the short circuit current of each of second photovoltaic cells corresponding to cells that are not selected among the set of photovoltaic cells;
arrange the set of photovoltaic cells adjacent to each other such that the first photovoltaic cells are arranged at the edges and/or the ends of the photovoltaic module;
make electrical connections between the set of photovoltaic cells.

A method of producing a photovoltaic module is also disclosed including at least the following steps:
select the photovoltaic cells with the lowest short circuit currents from among a plurality of photovoltaic cells that will form part of the photovoltaic module;
arrange said plurality of photovoltaic cells adjacent to each other, such that the photovoltaic cells that will be placed at the edges and/or ends of the photovoltaic module are the previously selected cells.

The photovoltaic cells are preferably electrically connected together in series.

The method may also comprise, before the step to select the first photovoltaic cells, a step of selection of said set of photovoltaic cells from among a larger number of photovoltaic cells such that the fill factor of each of the cells of said set of photovoltaic cells is greater than about 0.70, and advantageously greater than or equal to 0.75.

The set of photovoltaic cells of the photovoltaic module may be arranged adjacent to each other to form a rectangular-shaped matrix with M×N cells, and the photovoltaic module may comprise 2 (M+N−2) first photovoltaic cells, where M and N are integers greater than or equal to 3.

In this case, the method may also comprise a step to select four photovoltaic cells among the first photovoltaic cells, between the step to select the first photovoltaic cells and the step to arrange the photovoltaic cells of the module, the values of the short circuit currents of these four photovoltaic cells being the lowest, said four photovoltaic cells then being positioned at the corners of the rectangular matrix.

### BRIEF DESCRIPTION OF THE DRAWINGS

This invention will be better understood after reading the description of example embodiments given purely for information and that are in no way limitative with reference to the appended drawings in which:

FIG. 1 shows a photovoltaic module according to a particular embodiment of this invention;

FIG. 2 shows two photovoltaic modules, one of which corresponds to a particular embodiment of this invention;

FIG. 3 shows the values of fill factors and short circuit currents of the photovoltaic cells of the two modules shown in FIG. 2;

FIG. 4 shows the I(U) characteristics of the two modules shown in FIG. 2;

FIG. 5 shows a photovoltaic module according to another particular embodiment of this invention.

Identical, similar or equivalent parts of the different figures described below are assigned the same numeric references to facilitate comparison between different figures.

The different parts shown in the figures are not necessarily all at the same scale, to make the figures more easily readable.

The different possibilities (variants and embodiments) should be understood as not being exclusive of each other and they can be combined with each other.

### DETAILED PRESENTATION AND PARTICULAR EMBODIMENTS

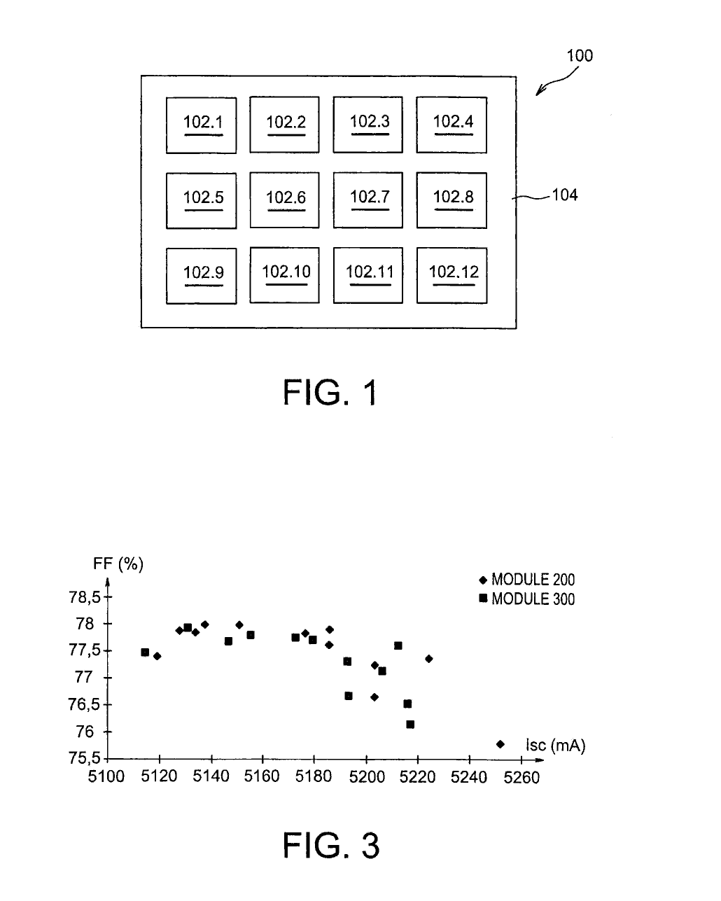

Refer firstly to FIG. 1 that diagrammatically shows a photovoltaic module 100 according to one particular embodiment.

The photovoltaic module 100 comprises twelve photovoltaic cells 102.1-102.12 electrically connected to each other, in this case in series, and mechanically assembled on a face of a chassis 104 in the form of a rectangular matrix with dimensions 3×4 (3 rows and 4 columns). The type and technology of the photovoltaic cells 102.1-102.12 may be chosen depending on the envisaged application of the photovoltaic module 100 and the required performances and cost for the module. Thus, the photovoltaic cells 102.1-102.12 may be composed of monocrystalline, amorphous or multicrystalline silicon, or they may be composed of one or several other semiconductors. They may also correspond to homo-junction or hetero-junction cells, they may comprise electrical contacts on the front and back faces or on the back face only, etc.

The photovoltaic cells 102.1-102.12 of the photovoltaic module 100 have a fill factor greater than or equal to about 0.70, or 70%, and advantageously greater than or equal to about 0.75, or 75%. The fill factor (FF) of a photovoltaic cell is equal to the ratio

$$\frac{Pm}{{V}_{OC} \times {I}_{SC}} ,$$

where Pm is the maximum power of the cell, V_{OC} is the open circuit voltage and I_{SC} is the short circuit current of the cell.

The position of each of the photovoltaic cells 102.1-102.12 within the rectangular matrix is chosen as a function of the value of the short circuit current I_{SC} of each cell in order to increase the global short circuit current of the photovoltaic module 100, and thus increase the photovoltaic conversion efficiency of the module 100. This is done by selecting those cells that have the lowest values of the short circuit current I_{SC} among the set of cells that will form the photovoltaic module 100. When the photovoltaic cells are assembled onto the chassis 104, these selected cells are located at the edges of the module 100.

Thus for example in FIG. 1, the ten among the twelve photovoltaic cells 102.1-102.12 that are arranged at the external edges of the photovoltaic module 100 (in this case corresponding to cells 102.1, 102.2, 102.3, 102.4, 102.5, 102.8, 102.9, 102.10, 102.11 and 102.12) are the ten cells among the twelve cells 102.1-102.12 that have the lowest values of the short circuit current. Therefore, the ten photovoltaic cells for which the short circuit currents are lowest among the initial set of twelve, will be chosen to be located at the edges of the module 100. These ten first photovoltaic cells may be considered as being positioned at the edges of the photovoltaic module 100, and around the periphery of, or around, second photovoltaic cells in this case corresponding to the two cells 102.6 and 102.7. Each of the first photovoltaic cells comprises at least one side that is not facing another photovoltaic cell of the module 100 (unlike cells 102.6 and 102.7 for which each of their four sides is facing another photovoltaic cell of the module).

Advantageously, the four first cells with the lowest short circuit currents among the twelve can be placed at the corners of the photovoltaic module 100, in order to further increase the short circuit current of the photovoltaic module 100. In the example in FIG. 1, these four cells correspond to cells referenced 102.1, 102.4, 102.9 and 102.12.

The photovoltaic module 100 may comprise a larger or smaller number of photovoltaic cells. For example, all photovoltaic cells of the photovoltaic module may be arranged adjacent to each other to form a rectangular matrix of M×N cells, M and N are integers greater than or equal to 3. In this case, the number of first photovoltaic cells, in other words cells that will be located at the external edges of the photovoltaic module, is 2(M+N−2). The number of second photovoltaic cells, in other words those that are surrounded by the first cells, is M·N−2(M+N−2). For example, for a photovoltaic module comprising 60 cells arranged in the form of a rectangular matrix, the 28 cells that have the lowest short circuit currents values are identified. These 28 cells, called first photovoltaic cells are the cells that will be arranged around the periphery, at the external edges of the photovoltaic module. The four cells having the lowest short circuit currents values will advantageously be arranged at the corners of the module. For example, this module may be made in the form of a rectangular matrix composed of six rows of ten photovoltaic cells, each cell for example being square in shape. The values of the short circuit currents of the four first photovoltaic cells located in the corners do not exceed a maximum value in this case denoted I_{SC1}. The values of the short circuit currents of the other 24 first photovoltaic cells located at the outside edges of the module are higher than I_{SC1} and do not exceed a maximum value denoted I_{SC2}. Finally, the 32 remaining photovoltaic cells called second photovoltaic cells are arranged at the centre of the photovoltaic module and are surrounded by the 28 first photovoltaic cells, with short circuit currents values higher than I_{SC2}.

Therefore in the above example, the photovoltaic cells are distributed in three categories: the cells with the lowest values of the short circuit current (values I_{SC} such that I_{SC}≦I_{SC1}) that are located at the four corners of the module, then the cells for which the value of the short circuit currents are slightly higher (values I_{SC} such that I_{SC1}<I_{SC1}≦I_{SC2}) located at the edges of the module, and finally the cells for which the values of the short circuit currents are highest (values I_{SC} such that I_{SC2}<I_{SC}) located at the centre of the module.

When the photovoltaic module is rectangular in shape, it may be advantageous to distribute the photovoltaic cells into four categories: cells with the lowest values of the short circuit current (values I_{SC} such that I_{SC}≦I_{SC1}) that are arranged at the corners of the module, then cells with slightly higher values of the short circuit current (values I_{SC} such that I_{SC1}<I_{SC}≦I_{SC2}) located at the edges of the module along the length of the module, then cells with slightly higher values of the short circuit currents (values I_{SC} such that I_{SC2}<I_{SC}≦I_{SC3}) located at the edges of the module along the width of the module, and finally the cells that have the highest short circuit values (values I_{SC} such that I_{SC3}<I_{SC}) located at the centre of the module.

Thus, for a photovoltaic module with 120 cells arranged in the form of a rectangular matrix for example comprising six rows of twenty photovoltaic cells, each cell for example being rectangular in shape, the four first photovoltaic cells that have the lowest values of the short circuit currents among the set of 120 cells are located at the four corners of the module. The values of the short circuit currents of these four first photovoltaic cells do not exceed a maximum value denoted I_{SC1}. 36 other first photovoltaic cells are arranged at the outside edges of the module along the length of the module (for example the top and bottom edges of the module) and the values of the short circuit currents are higher than I_{SC1} and do not exceed a maximum value denoted I_{SC2}. 8 other first photovoltaic cells are arranged at the outside edges of the module along the width of the module (for example the side edges of the module) and the values of the short circuit currents are higher than I_{SC2} and do not exceed a maximum value denoted I_{SC3}.

Finally, the 72 remaining photovoltaic cells called second photovoltaic cells are arranged at the centre of the photovoltaic module and are surrounded by the 48 first photovoltaic cells and for which the values of the short circuit current are higher than I_{SC3}.

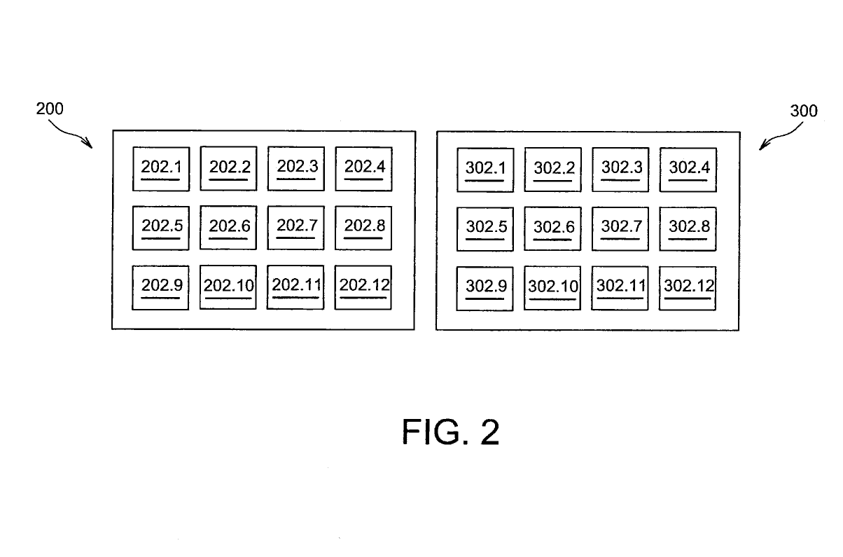

We will now describe the manufacturing method and we will compare the performances of two photovoltaic modules 200 and 300, module 200 being made by locating the photovoltaic cells with the lowest short circuit currents at the outside edges of the module 200, while module 300 is made by locating the photovoltaic cells with the highest short circuit currents at the outside edges of the module 300. These two modules 200 and 300 are shown in FIG. 2.

In order to make an objective comparison of the performances of the two modules 200 and 300, the photovoltaic cells used to make the two photovoltaic modules 200 and 300 are derived from the same batch of cells, with identical technologies, that will be used to make photovoltaic modules with approximately the same power. A first selection is made among all the cells in the batch, so as to keep only photovoltaic cells with a fill factor greater than or equal to about 0.70 and preferably greater than or equal to about 0.75, to make the two modules 200 and 300.

FIG. 3 shows values of the fill factor FF (the ordinate) as a function of the values of the short circuit current I_{SC} (the abscissa) of the 24 cells selected to make the two modules 200 and 300. The twelve diamonds represent the values of these characteristics for each of the twelve photovoltaic cells of the module 200, while the twelve squares represent the values of these characteristics for the twelve photovoltaic cells of the module 300. In this figure, it can be seen that the average values of fill factors and short circuit currents of the photovoltaic cells of the two modules 200 and 300 are very similar. It can also be seen that the limiting photovoltaic cell of each module 200 and 300 corresponding to the photovoltaic cell with the lowest value of the short circuit current is almost identical (very similar values of the short circuit current and almost identical fill factor) for the two modules.

The following table shows the sum of short circuit currents I_{SC} for photovoltaic cells of the module for each module 200 and 300, and the values of the mean and the standard deviation of short circuit currents I_{SC} and initial fill factors FF of cells of the module.

| | Module 200 | Module 300 |
|---|---|---|
| Sum I_{SC} (mA) | 62094.53 | 62138.86 |
| Mean I_{SC} (mA) | 5174.54 | 5178.24 |
| Standard deviation I_{SC} (mA) | 42.25 | 34.67 |
| Mean FF (%) | 77.45 | 77.3 |
| Standard deviation FF (%) | 0.65 | 0.57 |

Each of the modules 200 and 300 comprises twelve photovoltaic cells referenced 202.1-202.12 respectively for module 200 and 302.1-302.12 for module 300 arranged in the form of a 3×4 matrix, in a manner similar to that used for cells 102.1-102.12 in module 100. Therefore in module 200, photovoltaic cells 202.6 and 202.7 are surrounded by the other cells 202.1-202.5 and 202.8-202.12 and have the highest short circuit currents equal to about 5251 mA and 5223 mA respectively. The values of the short circuit currents of the other cells 202.1-202.5 and 202.8-202.12 are between about 5119 mA and 5202 mA. On the other hand in module 300, photovoltaic cells 302.6 and 302.7 that are surrounded by the other cells 302.1-302.5 and 302.8-302.12 have the lowest short circuit currents equal to about 5114 mA and 5130 mA respectively, the values of short circuit currents of the other cells 302.1-302.5 and 302.8-302.12 being between about 5146 mA and 5216 mA.

Therefore in module 200, the cells with the best photovoltaic conversion capacities are arranged at the centre of the module. The light emitting image of module 200 in operation shows a brighter zone at the centre of the module (at the position of cells 202.6 and 202.7) than at the edge of the module. In module 300, the cells with the best photovoltaic conversion capacities are located at the edges of the module. The light emitting image of module 300 in operation is more homogeneous than module 200.

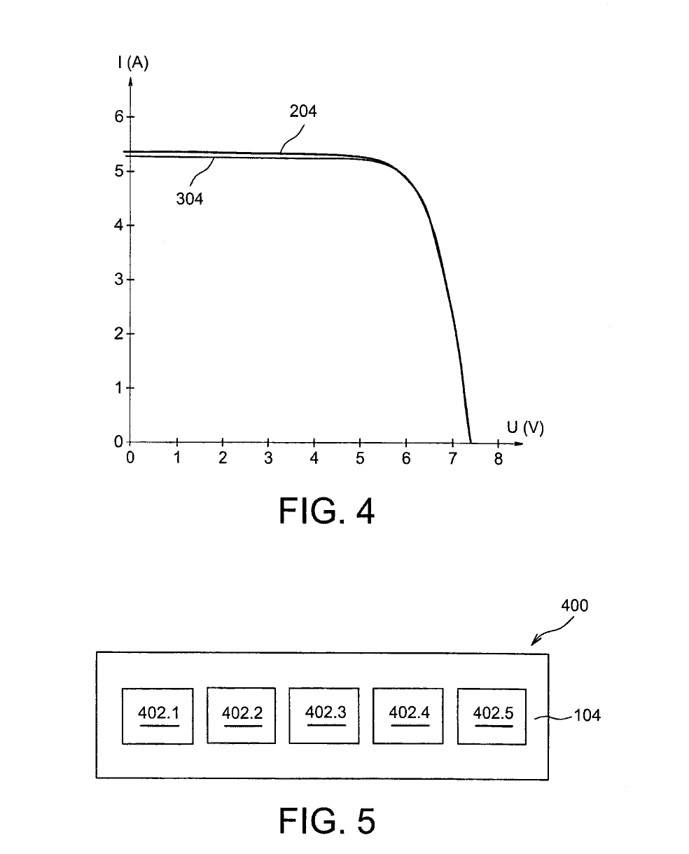

The curves 204 and 304 shown in FIG. 4 correspond to the characteristics I(U) of modules 200 and 300 respectively. Thus, it can be seen that the value of the short circuit current of module 200 is equal to 5.322 A, while the value of the short circuit current of module 300 is equal to 5.254 A, which represents a gain in the short circuit current of about 1.3%. Therefore, for a set of photovoltaic cells that will be used to make a photovoltaic module, it can be seen that the arrangement of the photovoltaic cells with the lowest values of short circuit currents at the edges of the module can increase the short circuit current of the module and therefore increase its photovoltaic conversion capacity.

FIG. 5 shows another example embodiment of a photovoltaic module 400 in which the arrangement of photovoltaic cells is optimised as a function of the values of the short circuit currents of these cells.

The photovoltaic module 400 comprises five photovoltaic cells referenced 402.1-402.5 arranged in the form of a single row of five cells. Among these five photovoltaic cells, the two cells 402.1 and 402.5 located at the ends of the row are chosen as being the cells among the five cells 402.1-402.5 that have the lowest short circuit currents. Therefore the two cells 402.1 and 402.5 are first photovoltaic cells that are located at the zones in the module in which the light reflected is strongest, the other photovoltaic cells 402.2-402.4 called second photovoltaic cells and that have the highest short circuit currents, are arranged at the centre of the module and therefore will be overilluminated relative to the first photovoltaic cells.

As a variant, the photovoltaic module could comprise two rows of photovoltaic cells. In this case, the four cells arranged at the ends of the two rows would be chosen among all the cells to be the cells with the lowest short circuit currents.

1-10. (canceled)

11. A photovoltaic module comprising:
first photovoltaic cells and second photovoltaic cells, electrically connected to each other and arranged adjacent to each other,
wherein each of the first photovoltaic cells has a short circuit current with a value less than a value of a short circuit current of each of the second photovoltaic cells of the photovoltaic module and are arranged at edges and/or ends of the photovoltaic module.

12. The photovoltaic module according to claim 11, wherein each photovoltaic cell of the photovoltaic module has a fill factor greater than about 0.70.

13. The photovoltaic module according to claim 11, wherein the photovoltaic cells of the photovoltaic module are arranged adjacent to each other to form a rectangular-shaped matrix of M×N cells, the photovoltaic module comprising 2(M+N−2) first photovoltaic cells, wherein M and N are integers greater than or equal to 3.

14. The photovoltaic module according to claim 13, wherein four first photovoltaic cells are arranged in corners of the rectangular-shaped matrix and the value of the short circuit current of each of the four first photovoltaic cells is less than or equal to the value of the short circuit current of each of the other first photovoltaic cells.

15. The photovoltaic module according to claim 11, wherein the photovoltaic cells of the photovoltaic module are arranged adjacent to each other to form one or two rows of P photovoltaic cells, the photovoltaic module comprising two or four first photovoltaic cells arranged at ends of the one or two rows of P photovoltaic cells, wherein P is an integer greater than or equal to 3.

16. A method of producing a photovoltaic module, comprising:
selecting first photovoltaic cells among a set of photovoltaic cells that will form part of the photovoltaic module, wherein a value of a short circuit current for each first photovoltaic cell is less than a value of a short circuit current of each of the second photovoltaic cells corresponding to cells that are not selected among the set of photovoltaic cells;
arranging the set of photovoltaic cells adjacent to each other such that the first photovoltaic cells are arranged at edges and/or the ends of the photovoltaic module;
making electrical connections between the set of photovoltaic cells.

17. The method according to claim 16, further comprising, before the selecting the first photovoltaic cells, selecting the set of photovoltaic cells from among a larger number of photovoltaic cells such that the fill factor of each of the cells of the set of photovoltaic cells is greater than about 0.70.

18. The method according to claim 16, wherein the set of photovoltaic cells of the photovoltaic module are arranged adjacent to each other to form a rectangular-shaped matrix with M×N cells, the photovoltaic module comprising 2(M+N 2) first photovoltaic cells, wherein M and N are integers greater than or equal to 3.

19. The method according to claim 18, further comprising selecting four photovoltaic cells among the first photovoltaic cells, between the selecting the first photovoltaic cells and the arranging the photovoltaic cells of the module, the values of the short circuit currents of the four photovoltaic cells being lowest, the four photovoltaic cells then being positioned at corners of the rectangular matrix.

20. The method according to claim 16, wherein the photovoltaic cells of the photovoltaic module are arranged adjacent to each other to form one or two rows of P photovoltaic cells, the photovoltaic module comprising two or four first photovoltaic cells arranged at ends of the one or two rows of P photovoltaic cells, wherein P is an integer greater than or equal to 3.
